(19) United States
(12) Patent Application Publication
(10) Pub. No.: US 2017/0005148 A1
(43) Pub. Date: Jan. 5, 2017

(54) ORGANIC LIGHT-EMITTING DISPLAY DEVICE

(71) Applicant: LG Display Co., Ltd., Seoul (KR)

(72) Inventor: SunKap KWON, Gyeonggi-do (KR)

(73) Assignee: LG Display Co., Ltd., Seoul (KR)

(21) Appl. No.: 15/173,906

(22) Filed: Jun. 6, 2016

(30) Foreign Application Priority Data
Jun. 30, 2015 (KR) 10-2015-0092689

(51) Int. Cl. H01L 27/32; H01L 51/56; H01L 51/52

(52) U.S. Cl. CPC H01L 27/3246; H01L 51/5209; H01L 51/5225; H01L 51/56

(57) ABSTRACT

An organic light-emitting display (OLED) device includes a plurality of anodes spaced apart from one another, a cathode disposed on the anodes in each pixel area, and a bank defining each pixel area and covering ends of each of the anodes. The bank has a concave side surface configured to minimize reduction in an emission area relative to the pixel area according to increase in thickness of an organic light-emitting element. Accordingly, the luminous efficiency of lifespan of the OLED device can be improved.

### CROSS-REFERENCE TO RELATED APPLICATIONS

This application claims the priority of Korean Patent Application No. 10-2015-0092689 filed on Jun. 30, 2015, in the Korean Intellectual Property Office, the disclosure of which is incorporated herein by reference.

### BACKGROUND

Technical Field

The present disclosure relates to an organic light-emitting display (OLED) device, and more specifically to an OLED device in which a bank defining a pixel area has a structure that minimizes reduction in an emission area according to increase in thickness of an organic light-emitting element, thereby improving the luminous efficiency and lifespan.

Description of the Related Art

An organic light-emitting display (OLED) device is a self-luminance display device and is emerging as the next generation display device. An OLED device, unlike a liquid-crystal display (LCD) device, does not require any additional light source and thus it can be made lighter and thinner. In addition, an OLED device is advantageous over an LCD device in terms of viewing angle, contrast, response time, power consumption, etc. Thus, the OLED device is attracting attention as the next generation display device.

An OLED device includes two electrodes and an organic light-emitting element that includes an organic emission layer interposed between the two electrodes. The organic light-emitting element is a self-luminous element that utilizes the phenomenon that holes and electrons injected from the two electrodes recombine in the organic emission layer to form excitons, and light of a particular wavelength is generated as energy is released.

In order to improve the properties of the organic light-emitting element such as the driving voltage or the luminous efficiency, additional organic layers having various functions may be further disposed between the two electrodes of the organic light-emitting element, as well as the organic emission layer. For example, a hole injection layer or a hole transport layer may be additionally disposed between one of the two electrodes, i.e., an anode and the organic emission layer, in order to facilitate injection or transport of holes from the anode to the organic emission layer. In addition, an electron injection layer or an electron transport layer may be additionally disposed between a cathode and the organic emission layer, in order to facilitate injection or transport of electrons from the cathode to the organic emission layer. The additional layers disposed between the respective two electrodes and the organic emission layer reduce difference in energy level between the two electrodes and the organic emission layer to facilitate movement of holes or electrons. Accordingly, the properties of the organic light-emitting element can be improved, such as reducing the driving voltage or improving the luminous efficiency.

However, the more organic layers the organic light-emitting element includes, the thicker the organic light-emitting element becomes. In particular, when an organic light-emitting element is to emit white light, it has a plurality of organic emission layers for emitting white light, e.g., a stack of a blue emission layer and a yellow emission layer between two electrodes, and accordingly the number of the organic emission layers increases and the organic light-emitting element becomes even thicker.

As the organic light-emitting element becomes thicker, there is a problem in that an emission area EA of the OLED device becomes smaller. This will be described in more detail with reference to FIGS. 1A and 1B.

FIG. 1A is a plan view of a general OLED device 100. FIG. 1B is a cross-sectional view taken along line I-I′ of FIG. 1A.

Referring to FIG. 1B, an organic light-emitting element 120 is disposed on a substrate 110. The organic light-emitting element 120 includes an anode 121, an organic light-emitting unit 122 and a cathode 123. In addition, a bank 130 is disposed that includes an opening via which a part of the anode 121 is exposed. The organic light-emitting unit 122 includes a plurality of organic layers including an organic emission layer. The organic light-emitting unit 122 is disposed on the anode 121 and the bank 130. Specifically, the organic light-emitting unit 122 is disposed on a first surface 121T having a flat surface of the anode 121 exposed via the opening of the back 130 and extended to a top surface of the bank 130 along a side surface 130S of the bank 130. The side surface 130S of the bank 130 generally has a convex shape as shown in FIG. 1B. The organic light-emitting unit 122 and the cathode 123 also have the convex shape conforming to the side surface 130S of the bank 130.

Referring to FIGS. 1A and 1B, the OLED device 100 includes a plurality of pixel areas PAs on the substrate 110. A pixel area PA refers to a unit area from which light is emitted and may be referred to as a pixel or a sub-pixel. Each of the pixel areas PAs of the OLED device 100 may be a region opened by the bank 130 and may be defined by a portion where the anode 121 and the bank 130 are in contact with each other. Alternatively, the pixel area PA may correspond to the first surface 121T of the anode 121 exposed via an opening of the bank 130. That is, the pixel area PA may be equal to the area of the first surface 121T of the anode 121.

The aperture ratio of the OLED device 100 may be determined depending on the ratio of the pixel areas PAs. The aperture ratio refers to a percentage representing the portion of a transmissive area of the total area of a panel, i.e. OLED device 100. An OLED device having higher aperture ratio has higher luminous efficiency and longer lifespan. Accordingly, various technologies to improve the aperture ratio are under development.

As mentioned earlier, as the organic light-emitting element 120 becomes thicker, there may be the problem in that the emission area EA of the OLED device 100 becomes smaller. The emission area EA refers to the portion in a pixel area PA from which light is emitted normally. Specifically, the emission area EA refers to the area where the anode 121 is parallel with the cathode 123. In FIG. 1B, the emission area EA corresponds to a second surface 123T that is the flat top surface of the cathode 123 and may be equal to the area of the second surface 123T of the cathode 123.

In order to increase the efficiency of the OLED device 120, holes from the anode 121 and electrons from the cathode 123 have to be injected readily into the organic emission layer. To this end, the anode 121 and the cathode 123 have to be parallel with each other. That is, the efficiency of the OLED device 120 can be increased only when the organic light-emitting unit 122 and the cathode 123 are disposed in parallel with the flat anode 121.

Referring to FIGS. 1A and 1B, in the pixel area PA where the organic light-emitting unit 122 and the cathode 123 are formed over the anode 121 and the bank 130, there is a portion X where the anode 121 is not parallel with the cathode 123 due to the convex side surface 130A of the bank 130. The probability of recombination of holes and electrons decreases in the organic emission layer in the portion X where the anode 121 is not parallel with the cathode 123. Accordingly, the luminous efficiency of the organic light-emitting element 120 may also decrease.

In addition, to maximize the efficiency of the organic light-emitting element 120, the anode 121 has to be parallel with the cathode 123, and thus the distance between the anode 121 and the cathode 123 has to be constant in the pixel area PA. However, as shown in FIG. 1B, the distance between the anode 121 and the cathode 123 in the pixel area PA may become different according to the shape of the bank 130. Specifically, a distance D1′ in the portion X where the anode 121 is not parallel with the cathode 123 may be larger than a distance D1 in the emission area EA where the anode 121 is parallel with the cathode 123.

In particular, as the organic light-emitting element 120 becomes thicker, the portion X where the anode 121 is not parallel with the cathode 123 becomes larger. That is, as the organic light-emitting element 120 becomes thicker, the portion X where the probability of recombination of holes and electrons in the pixel area PA is low may also become larger. As a result, the organic light-emitting element 120 fails to normally work throughout the entire portion of pixel area PA, and the luminous efficiency of the organic light-emitting element 120 may decrease.

In other words, since light cannot be emitted throughout the entire portion of the pixel area PA of the OLED device 100, the aperture ratio of the OLED device 100, which represents the portion of the transmissive area, may be determined by the emission area EA from which the light actually exits, not by the pixel area PA. Accordingly, the aperture ratio of the OLED device 100 becomes lower than the designed value determined based on the pixel area PA, and thus the luminous efficiency and lifespan of the OLED device 100 may be lowered.

### SUMMARY

Accordingly, the present invention is directed to an organic light-emitting display (OLED) device that substantially obviates one or more of the problems due to limitations and disadvantages of the related art.

In view of the above, an object of the present disclosure is to provide an OLED device in which a bank defining a pixel area has a concave side surface that minimizes reduction in an emission area due to increase in thickness of an organic light-emitting element, thereby improving the luminous efficiency and lifespan.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an organic light-emitting display (OLED) device comprises an organic light-emitting element comprising a plurality of anodes spaced apart from one another and a cathode on the anodes in each of pixel areas, and a bank defining each pixel area and covering ends of each of the anodes. The bank has a concave side surface configured to minimize reduction in an emission area relative to the pixel area according to increase in thickness of an organic light-emitting element. Accordingly, the luminous efficiency of lifespan of the OLED device can be improved.

According to another aspect of the present disclosure, there is provided an OLED device including an anode on a substrate; a bank which surrounds the anode and exposes a first surface of the anode; an organic light-emitting unit on the anode; and a cathode on the organic light-emitting unit, comprising a second surface in parallel with the first surface of the anode. The bank has a structure that makes the area of the second surface of the cathode equal to or larger than an area of the first surface of the anode. Thus, the size of the pixel area of the OLED device may be equal to the size of the emission area of the OLED device, thereby improving the luminous efficiency and lifespan of the OLED device.

According to yet another aspect of the present disclosure, there is provided an OLED device including a substrate comprising a pixel area; an organic light-emitting element on the substrate, comprising an anode, cathode and an organic light-emitting unit, and a bank which surrounds the anode and covers ends of the anode. The pixel area is defined by a contact of a top surface of the anode and the bank. The anode is parallel with the cathode in the pixel area. Accordingly, it is possible to minimize reduction in the emission area relative to the pixel area, thus the luminous efficiency and lifespan of the OLED device can be improved.

According to an exemplary embodiment of the present disclosure, a bank has a concave side surface to minimize reduction in an emission area relative to the pixel area according to increase in thickness of an organic light-emitting element.

Accordingly, it is possible to mitigate the problem that the aperture ratio of the OLED device is lowered, and the luminous efficiency and lifespan of the OLED device can be improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1A is a plan view of a general OLED device 100;

FIG. 1B is a cross-sectional view taken along line I-I′ of FIG. 1A;

FIG. 2A is a plan view of an OLED device according to an exemplary embodiment of the present disclosure;

FIG. 2B is a cross-sectional view taken along the line II-II′ of FIG. 2A;

FIG. 3 shows cross-sectional views of OLED devices according to Exemplary Embodiments and Comparative Examples having different side surface shapes of banks and different angles;

FIG. 4 is a table showing lifespans of OLED devices according to Exemplary Embodiments and Comparative Example depending on side surface shapes of banks; and

FIGS. 5A and 5B are cross-sectional views for illustrating a method for forming a bank according to an exemplary embodiment of the present disclosure.

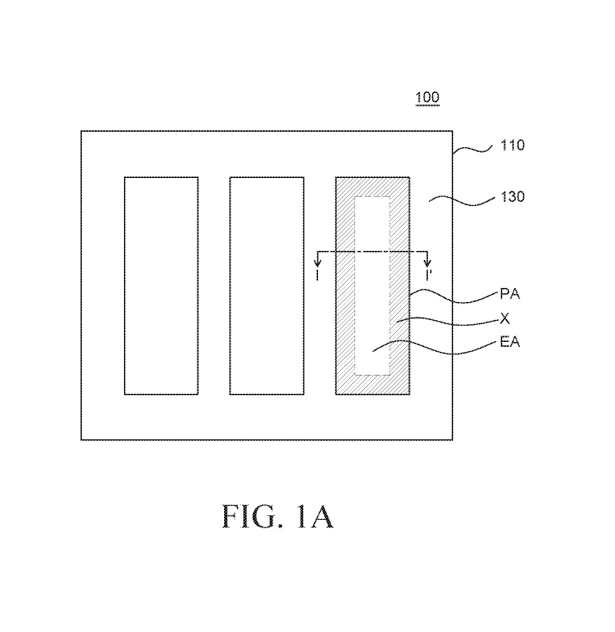

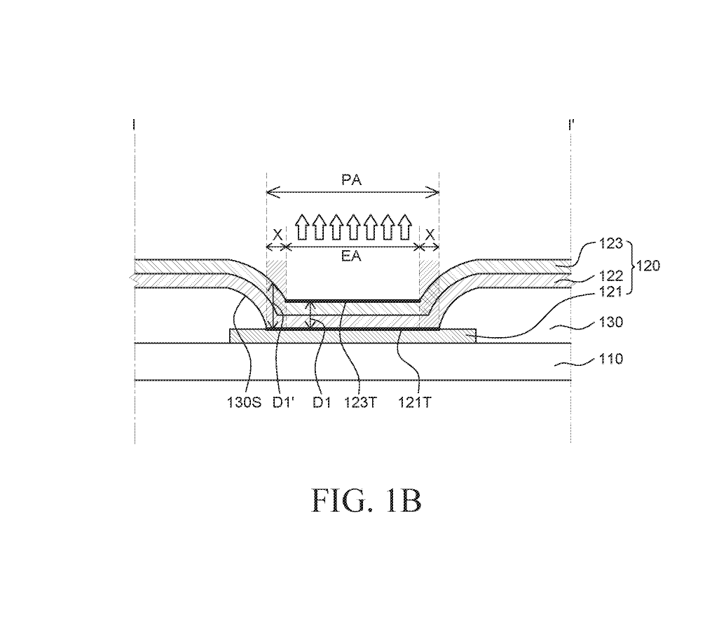

### DETAILED DESCRIPTION

Advantages and features of the present disclosure and methods to achieve them will become apparent from the descriptions of exemplary embodiments herein with reference to the accompanying drawings. However, the present invention is not limited to exemplary embodiments disclosed herein but may be implemented in various different ways. The exemplary embodiments are provided for making the disclosure of the present invention thorough and for fully conveying the scope of the present invention to those skilled in the art. It is to be noted that the scope of the present invention is defined only by the claims.

The figures, dimensions, ratios, angles, the numbers of elements given in the drawings are merely illustrative and are not limiting. Like reference numerals denote like elements throughout the descriptions. Further, in describing the present disclosure, descriptions on well-known technologies may be omitted in order not to obscure the gist of the present disclosure.

It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g. “a,” “an,” “the,” this includes a plural of that noun unless specifically stated otherwise.

In describing elements, they are interpreted as including error margins even without explicit statements.

In describing positional relationship, such as “an element A on an element B,” “an element A above an element B,” “an element A below an element B” and “an element A next to an element B,” another element C may be disposed between the elements A and B unless the term “directly” or “immediately” is explicitly used.

In describing temporal relationship, terms such as “after, ” “subsequent to, ” “next to” and “before” are not limited to “directly after,” “directly subsequent to,” “immediately next to” “immediately before,” and so on, unless otherwise specified.

The terms first, second, third and the like in the descriptions and in the claims are used for distinguishing between similar elements and not necessarily for describing a sequential or chronological order. These terms are used to merely distinguish one element from another. Accordingly, as used herein, a first element may be a second element within the technical idea of the present disclosure.

The drawings are not to scale and the relative dimensions of various elements in the drawings are depicted schematically and not necessarily to scale.

Features of various exemplary embodiments of the present disclosure may be combined partially or totally. As will be clearly appreciated by those skilled in the art, technically various interactions and operations are possible. Various exemplary embodiments can be practiced individually or in combination.

Hereinafter, organic light-emitting display (OLED) devices according to exemplary embodiments of the present disclosure will be described with reference to the accompanying drawings.

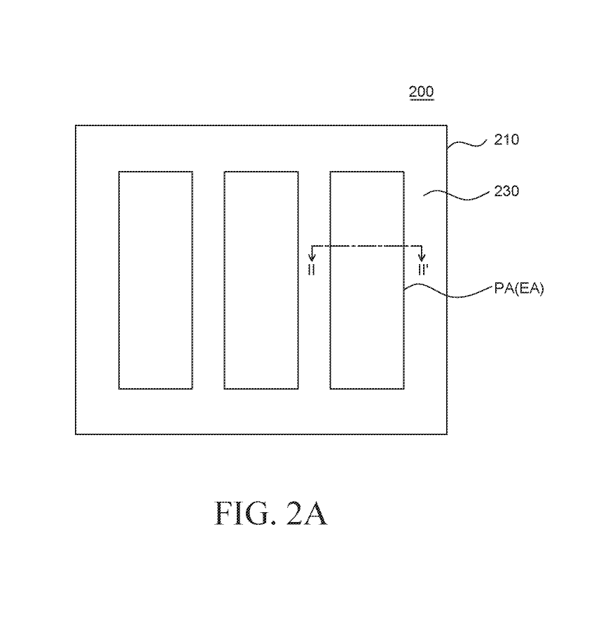

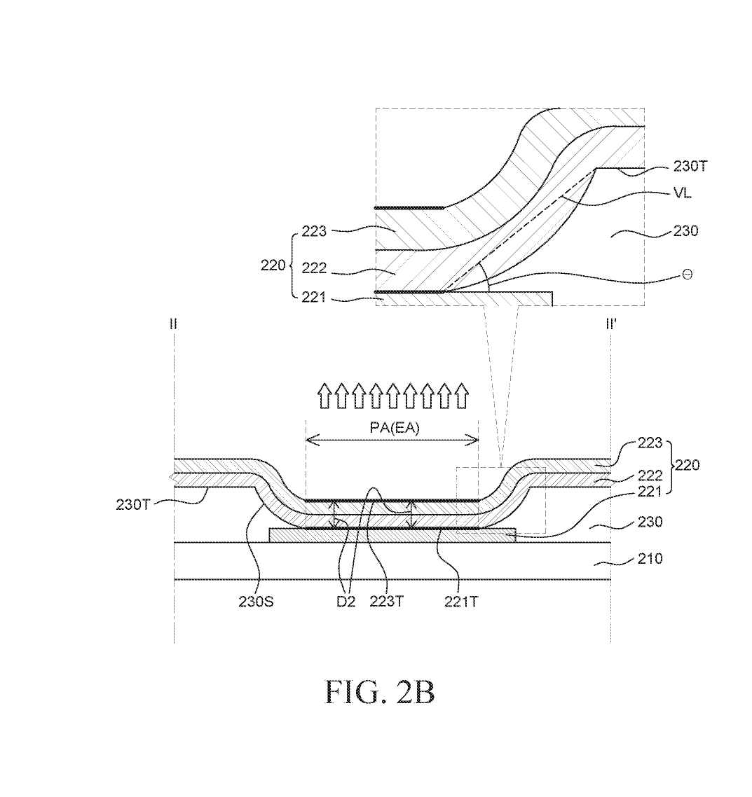

FIG. 2A is a plan view of an OLED device 200 according to an exemplary embodiment of the present disclosure. FIG. 2B is a cross-sectional view taken along the line II-II′ of FIG. 2A.

Referring to FIGS. 2A and 2B, an OLED device 200 includes a substrate 210, an organic light-emitting element 220 and a bank 230. The organic light-emitting element 220 is disposed on the substrate 210 and includes an anode 221, an organic light-emitting unit 222 and a cathode 223.

The substrate 210 may be formed of an insulative material such as glass or a flexible film formed of a polyimide-based material.

The substrate 210 includes pixel areas PAs. A pixel area PA refers to a unit area from which light is emitted and may be referred to as a pixel or a sub-pixel. The pixel area PA may be defined by the anode 221 and the bank 230, more specifically by a top surface of the anode 221 and the bank 230. Alternatively, the pixel area PA is defined by the top surface of the anode 221 and the bank 230. The pixel area PA corresponds to a first surface 221T, i.e., a part of the top surface of the anode 221 exposed via an opening of the bank 230. The pixel area PA may be equal to the area of the first surface 221T of the anode 221.

A plurality of anodes are disposed on the substrate 210 such that they are spaced apart from one another, each in the respective pixel areas PAs. The anode 221 is an electrode for supplying holes into an organic emission layer in the organic light-emitting unit 222. Each of the anodes 221 is connected to at least one thin-film transistor or capacitor to receive a driving signal. The anode 221 may be formed of a transparent conductive oxide (TCO) such as indium tin oxide (ITO) and indium zinc oxide (IZO). If the OLED device 200 is a top-emission OLED device, the anode 221 may further include a reflective layer formed of a metal material.

The bank 230 defines each of the pixel areas PAs and covers the ends of each of the anodes 221. Referring to FIGS. 2A and 2B, the bank 230 surrounds the anode 221 and exposes the first surface 221T that is a part of the top surface of anode 221. The bank 230 may be formed of an organic material including, but is not limited to, polyimide or acryl resin.

The organic light-emitting unit 222 is disposed on the anode 221 and the bank 230 between the anode 221 and the cathode 223 and may include a plurality of organic layers including an organic emission layer. For example, the organic light-emitting unit 222 may include some or all of a hole injection layer, a hole transport layer, an organic emission layer, an electron transport layer, an electron injection layer, and a charge generation layer. In addition, the organic light-emitting unit 222 may include a plurality of organic emission layers depending on the design of the organic light-emitting element 220 and may include at least one among a blue emission layer and a yellow-green emission layer, for example.

The organic light-emitting unit 222 may be disposed at least some portion of the first surface 221T of the anode 221, the side surfaces 230S of the bank 230 and the top surface 230T of the bank 230 depending on the design of the organic light-emitting element 220. In other words, the organic light-emitting unit 222 is disposed on the first surface 221T of the anode 221 exposed via the opening of the bank 230 and extended to the top surface 230T of the bank 230 along the side surfaces 230S of the bank 230.

For example, all of the organic layers included in the organic light-emitting unit 222 may be extended on the first surface 221T of the anode 221, the side surfaces 230S of the bank 230 and the entire top surface 230T of the bank 230. That is, the organic light-emitting unit 222 may be shared by the pixel areas PAs.

Alternatively, among the organic layers, some organic layers may be disposed on the first surface 221T of the anode 221, the side surfaces 230S of the bank 230 and the entire top surface 230T of the bank 230, whereas the others may be disposed only a part of the top surface 230T of the bank 230. Specifically, among the organic layers, organic emission layers may be separated from one another, each disposed in a pixel area, whereas a common layer such as a hole transport layer may be shared by the pixel areas PAs or may be disposed across the pixel area PAs.

Alternatively, all of the organic layers included in the organic light-emitting unit 222 may be disposed on the first surface 221T of the anode 221, the side surfaces 230S of the bank 230 and only a part of the top surface 230T of the bank 230. That is, all of the organic layers may be separated from one another, each disposed in a pixel area.

The cathode 223 is an electrode for supplying electrons and is disposed on the organic light-emitting unit 222 such that it is shared by the pixel areas PAs. In other words, the cathode 223 is disposed on the anode 221 that is spaced apart from one another, each disposed in a pixel area PA. The cathode 223 may be formed of a transparent conductive oxide (TCO) such as indium tin oxide (ITO) and indium zinc oxide (IZO).

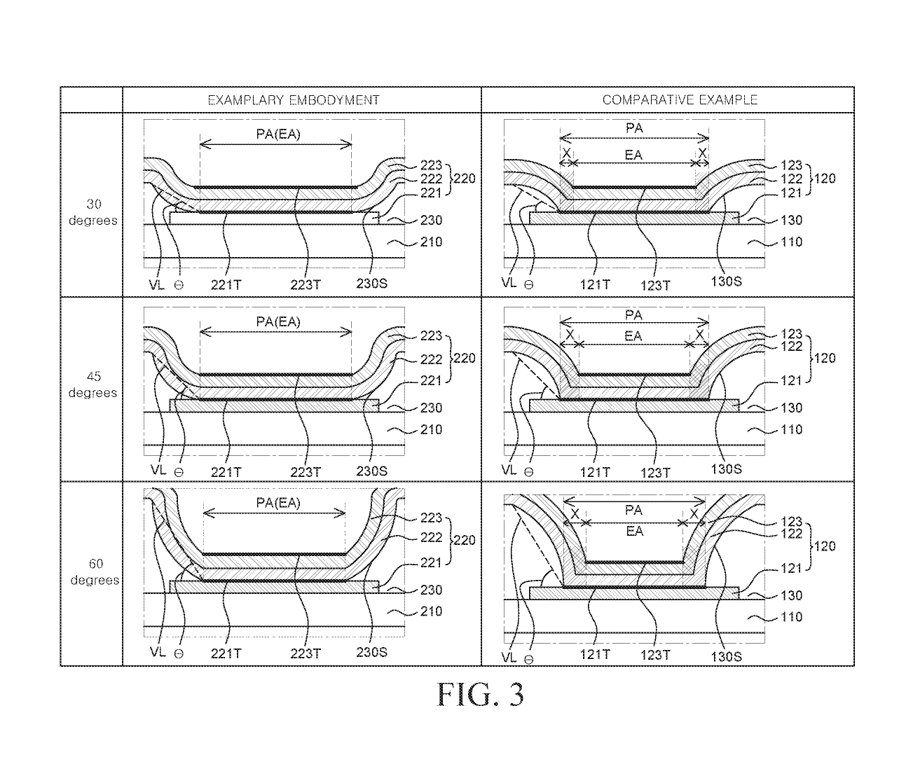

In the OLED device 200 according to the exemplary embodiment of the present disclosure, the bank 230 has a concaved side surfaces 230S as shown in FIG. 2B, which minimizes reduction in the emission area EA relative to the pixel area PA due to increase in thickness of the organic light-emitting element 220. The emission area EA refers to the portion in the pixel area PA from which light is emitted normally. Specifically, the emission area EA refers to the area where the anode 221 is parallel with the cathode 223. In FIG. 2B, the emission area EA may correspond to the first surface 221T of the anode 221 or the second surface 223T of the cathode 223 in parallel to the first surface 221T. That is, the emission area EA may be equal to the area of the first surface 221T of the anode 221 or the second surface 223T of the cathode 223. However, the area of the second surface 223T of the cathode 223 may be larger than the emission area EA or the area of the first surface 221T of the anode 221 depending on a side surface angle θ of bank 230. This will be described in detail below with reference to FIG. 3.

As the side surface 230S of the bank 230 that defines each of the pixel areas PAs has the concaved shape as shown in FIG. 2B, the organic light-emitting unit 222 and the cathode 223, which cover the side surface 230S of the bank 230, may also be disposed in the concaved shape conforming to the side surface 230A of the bank 230. As used herein, the concave side surface 230S of the bank 230 refers to that the side surface 230S of the bank 230 is disposed on the inner side with respect to a virtual line VL that is extended from one end to the other end of the side surface 230S of the bank 230 in cross section. In other words, the concave side surface 230S of bank 230 is disposed lower than the virtual line VL.

As described above, holes and electrons can be injected normally and readily into the organic emission layer only when the anode 221 and the cathode 223 are in parallel with each other, such that the efficiency of the OLED device 220 can be increased. However, there may be a portion where the anode 221 is not parallel with the cathode 223 in the pixel area PA depending on the side surface shape of the bank 230, such that the luminous efficiency of the organic light-emitting element 220 may be lowered.

According to the exemplary embodiment of the present disclosure, the bank 230 has concave side surfaces such that the anode 221 is parallel with the cathode 223 in the entire pixel area PA. Accordingly, the distance between the anode 221 and the cathode 223 becomes constant in the pixel area PA. That is, the pixel area PA and the emission area EA correspond to each other and they have the same size. In other words, there is formed no portion X where the anode 221 is not parallel with the cathode 223, and thus light can be emitted normally throughout the entire pixel area PA of the OLED device 200. Accordingly, the aperture ratio of the OLED device 200 can meet the desired design value determined based on the pixel area PA. Thus, it is possible to solve the problem that the luminous efficiency and lifespan of the organic light-emitting element 220 or the OLED device 100 is lowered.

Referring to FIG. 2B, the bank 230 has an opening via which a part of the anode 221 is exposed. The bottom surface of the opening may correspond to the first surface 221T of the anode 221. The side surfaces of the opening correspond to the side surfaces of the bank 230 may be have a convex shape. Since the opening has the convex side surface, the area of the second surface 223T of the cathode that is parallel with the first surface 221T of the anode 221 may be equal to the area of the bottom surface of the opening or the first surface 221T of the anode 221. That is, the size of the pixel area PA may be equal to the size of the emission area EA. Accordingly, the light can be emitted normally from the organic light-emitting element 220 throughout the entire pixel area PA.

FIG. 3 shows cross-sectional views of OLED devices according to Exemplary Embodiments and Comparative Examples having different side surface shapes of banks and different angles. Specifically, the banks of the OLED devices according to Comparative Examples have a convex side surface with different side surface angles. And, the banks of the OLED devices according to Exemplary Embodiments have a concave side surface with different side surface angles.

Firstly, referring to Comparative Examples, a side surface 130S of a bank 130 has a convex shape. The convex side surface 130S of the bank 130 refers to that the side surface 130S of bank 130 protrudes from a virtual line VL that is extended from one end to the other end of the side surface 130S of the bank 130 in cross section. In other words, the convex side surface 130S of bank 130 is disposed higher than the virtual line VL. The side surface angle θ of the bank 130 refers to the angle between the top surface of the anode 121 in contact with the bank 130 and the virtual line VL.

In Comparative Example with the side surface angle of 30 degrees, an organic light-emitting unit 122 and a cathode 123 are disposed in a convex shape conforming to the convex side surface 130S of the bank 130. Accordingly, the emission area EA where the anode 121 and the cathode 123 are disposed in parallel is smaller than the pixel area PA that corresponds to the first surface 121T that is the top surface of the anode 121 exposed via the opening of the bank 130. That is, there is a portion X where the anode 121 is not parallel with the cathode 123 in the pixel area PA, and thus the luminous efficiency of the organic light-emitting element 120 may be lowered.

Next, in Comparative Example with the side surface angle of 45 degrees, there also is a portion X where the anode 121 is not parallel with the cathode 123 in the pixel area PA. With the same thicknesses of the organic light-emitting unit 122 and the cathode 123, the portion X in Comparative Example with the side surface angle of 45 degrees becomes larger than the portion X in Comparative Example with the side surface angle of 30 degrees.

Likewise, the portion X in Comparative Example with the side surface angle of 60 degrees becomes larger than the portion X in Comparative Example with the side surface angle of 45 degrees.

That is, the larger the side surface angle θ of the bank 130 becomes, the sharper the convex shape of the side surface 130S of the bank 130 becomes, and thus the larger the portion X where the anode 121 is not parallel with the cathode 123 in the pixel area PA becomes. It can be seen that this leads to the problem that the emission area EA in the pixel area PA becomes smaller and smaller.

In contrast, referring to Exemplary Embodiments, a side surface 230S of a bank 230 has a concave shape. As mentioned earlier, the concave side surface 230S of the bank 230 refers to that the side surface 230S of the bank 230 is disposed on the inner side with respect to a virtual line VL that is extended from one end to the other end of the side surface 230S of the bank 230 in cross section. In other words, the concave side surface 230S of bank 230 is disposed lower than the virtual line VL. The side surface angle θ of the bank 230 refers to the angle between the top surface of the anode 221 in contact with the bank 230 and the virtual line VL.

In the OLED device according to Exemplary Embodiments, an organic light-emitting unit 222 and a cathode 223 are disposed in a concave shape conforming to the concave side surface 230S of the bank 230, with different side surface angle θ of the bank 230. Accordingly, the emission area EA where the anode 221 and the cathode 223 are disposed in parallel is equal to the pixel area PA that corresponds to the first surface 221T that is the top surface of the anode 221 exposed via the opening of the bank 230. That is, there is no portion where the anode 221 is not parallel with the cathode 223 in the pixel area PA, and thus it is possible to solve the problem that the luminous efficiency of the organic light-emitting element 220 is lowered.

However, the area of the second surface 223T of the cathode 223 in parallel with the first surface 221T of the anode 221 may vary depending on the side surface angle θ of bank 230. More specifically, according to Exemplary Embodiments with the side surface of 45 degrees or 60 degrees, the area of the second surface 223T of the cathode 223 may be equal to the first surface 221T of anode 221, the pixel area PA may be equal to the emission area EA as well. In contrast, according to Exemplary Embodiments with the side surface of 30 degrees, the area of the second surface 223T of the cathode 223 may be larger than the area of the first surface 221T of the anode 221.

That is, if the side surface angle θ of the bank 230 is larger than 45 degrees, i.e., the sharper the side surface of the bank 230 is, the more it is likely that the second surface 223T of the cathode 223 becomes smaller than the first surface 221T of the anode 221 depending on manufacturing errors or processing margins during the process of forming the organic light-emitting unit 222, the cathode 223 or the bank 230. This may lead to the problem that the emission area EA becomes smaller than the pixel area PA.

Therefore, in order to solve the problem, it may be desired that the side surface angle θ of the bank 230 is less than 45 degrees. By doing so, it is possible to reduce the problem that the second surface 223T of the cathode 223 becomes less than the first surface 221T of the anode 221 due to unexpected manufacturing errors or margins during the manufacturing process. In addition, it is more effective to make the size of the pixel area PA equal to that of the emission area more stably. The side surface angle θ of the bank 230 less than 45 degrees means that the angle made by the virtual line VL that is extended from one end to the other end of the side surface 230S of the bank 230 and the bottom surface of the opening of the bank 230 via which the first surface 221T of the anode 221 is exposed is larger than 135 degrees. In other words, the angle made by the virtual line VL that is extended from one end to the other end of the side surface 230S of the bank 230 and the first surface 221T of the anode 221 is larger than 135 degrees.

In the OLED device according to an exemplary embodiment of the present disclosure, the bank 230 has a structure in which that area of a surface of the cathode 223 in parallel with a part of the anode 221 exposed via the opening of the bank 230 is equal to or larger than the area of the bottom surface of the opening, such that the size of the pixel area PA may be equal to that of the emission area EA. In other words, the bank 230 has the structure in which the second surface 223T of the cathode 223 is equal to or larger than the first surface 221T of the anode 221, such that the size of the pixel area PA may be equal to the size of the emission area EA.

With the structure, it is possible to mitigate the problem that the emission area EA becomes smaller relative to the pixel area PA even if the thickness of the organic light-emitting element 220 is increased. That is, it is possible to mitigate the problem that the aperture ratio of the OLED device is lowered as the emission area EA becomes smaller, and thus it is possible to reduce the problem that the luminous efficiency and lifespan of the OLED device are lowered. In addition, by making the side surface angle θ of the bank 230 less than 45 degrees, it is possible to make the size of the pixel area PA be equal to that of the emission area EA more stably.

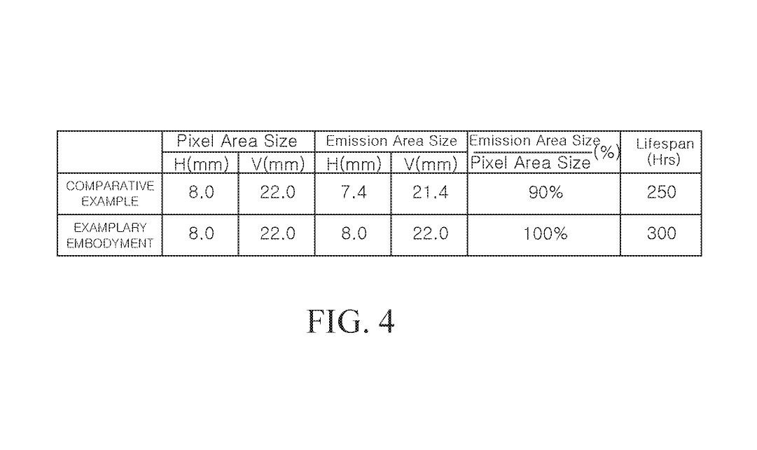

FIG. 4 is a table showing lifespans of OLED devices according to Exemplary Embodiment and Comparative Example depending on side surface shapes of banks.

Referring to the table shown in FIG. 4, the bank according to in Comparative Example has a convex side surface and the size of the pixel area (horizontal and vertical lengths) is 8.0 μm by 22.0 μm. That is, the size of the first surface of the anode exposed via the opening of the bank is 8.0 μm×22.0 μm=176 μm². On the other hand, the bank according to Exemplary Embodiment has a concave side surface and the size of the pixel area is 8.0 μm×22.0 μm=176 μm², which is equal to that of Comparative Example. In both of Comparative Example and Exemplary Embodiment, the thickness of the organic light-emitting unit is approximately 300 nm.

In Comparative Example, as the bank has the convex side surface, the size of the emission area where the anode is parallel with the cathode becomes 7.4 μm×21.4 μm=158.36 μm². This is approximately 90% of the size of the pixel area, i.e., the emission area is smaller than the pixel area.

In contrast, according to Exemplary Embodiment, the bank has the concave shape and thus the size of the emission area where the anode is parallel with the cathode becomes equal to that of the pixel area.

The same driving voltage was applied to the structures according to Exemplary Embodiment and Comparative Example, and times taken until the brightness of the OLED devices decrease to a particular level were measured. The structure according to Comparative Example exhibited approximately 250 hours, and the structure according to Exemplary Embodiment exhibited approximately 300 hours, which is increased by approximately 50 hours compared with the Comparative Example.

Accordingly, it can be seen that the bank according to an exemplary embodiment of the present disclosure has the concave side surface that minimizes reduction in the emission area relative to the pixel area, thereby improving the luminous efficiency and lifespan of the OLED device.

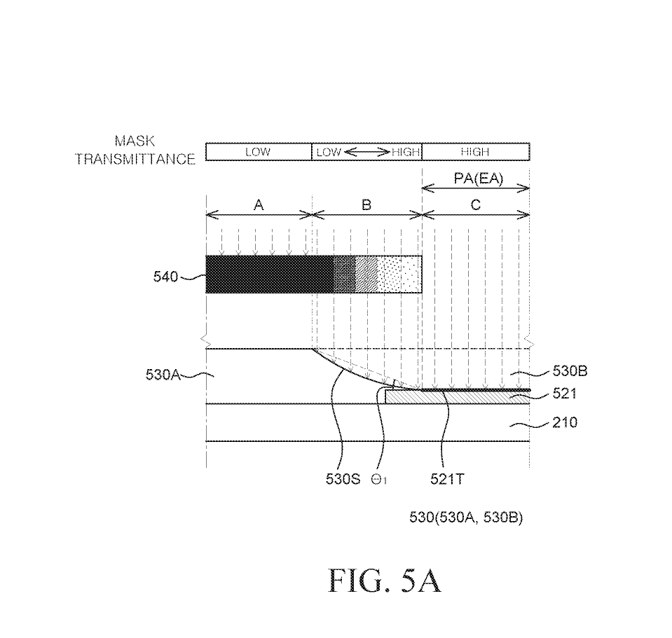

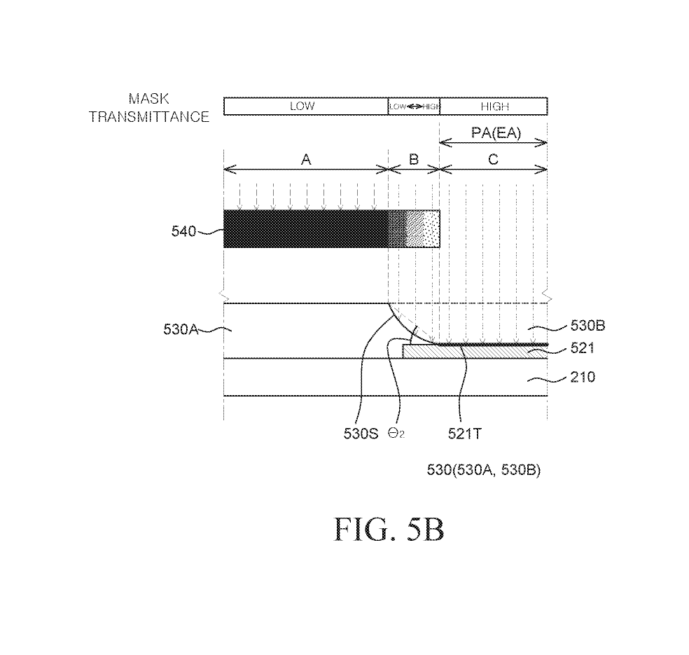

FIGS. 5A and 5B are cross-sectional views for illustrating a method for forming a bank according to an exemplary embodiment of the present disclosure.

Referring to FIGS. 5A and 5B, the bank can be formed by using a mask having a region where light transmittance gradually changes. It can be seen that the side surface angle of the bank changes depending on the size or width of the region of the mask. The method will be described in detail below.

A bank 530A may be formed in such a manner that a photoresist is formed on an anode 521, light is irradiated onto a particular portion of the photoresist using a mask 540, and then the irradiated portion is removed.

Initially, referring to FIG. 5A, a photoresist 530 is formed such that it covers a plurality of anodes 521 disposed on a substrate 210. Then, light is irradiated onto the photoresist 530 by using the mask 540 having a region where light transmittance gradually changes. More specifically, the mask 540 includes region C that is an opened portion through which light transmits for exposing a first surface 521T of the anode 521, i.e., for forming a pixel area PA, region A through which light cannot transmit for preserving the photoresist 530, and region B between region C and region A through which light transmits gradually for forming a side surface 530A of the bank 530A. In other words, region A has the highest light transmittance, region C has the lowest light transmittance, and region B between the region A and region C has light transmittance that gradually increases from region A to region C.

After light is irradiated onto the photoresist resin 530 by using the mask 540 shown in FIG. 5A and then the photoresist resin 530 is developed, a part 530B of the photoresist 530 in regions C and B is removed, and the other part becomes the bank 530A. The side surface 530S of the bank 530A may have a concave shape by region B through which light is gradually transmitted. Specifically, since the light transmittance of region B of the mask 540 gradually increases from a portion adjacent to region A to a portion adjacent to region C, the amount of the transmitted light of region B of the mask 540 may be changed. Thus, the side surface 531S of the bank 530A may have the concaved slope as shown in FIG. 5A.

The side surface angle θ of the bank 530A may be adjusted by changing the size or width of region B through which the light is gradually transmitted. Referring to FIG. 5B, it can be seen that the side surface angle θ2 of the bank 530A becomes larger as the size or the width of region B of the mask 540 becomes smaller. Referring to FIG. 5A, it can be seen that the side surface angle θ1 of the bank 530A becomes smaller as the size or the width of region B of the mask 540 becomes larger. That is, it can be seen that the side surface angle θ of the bank 530A may be adjusted by changing the size or width of region B that has gradually-changing transmittance.

According to an exemplary embodiment of the present disclosure, the bank 530A has a concave side surface formed by using the mask 540 having gradually-changing light transmittance in region B such that the size of the pixel area PA is equal to that of the emission area EA. As a result, the luminous efficiency and lifespan of the OLED device can be improved.

The exemplary embodiments of the present disclosure can also be described as follows.

According to an aspect of the present disclosure, an organic light-emitting display (OLED) device includes an anode on a substrate, a bank which surrounds the anode and exposes a first surface of the anode, and a cathode on the organic light-emitting unit, comprising a second surface in parallel with the first surface of the anode. The bank has a structure that makes an area of the second surface of the cathode equal to or larger than an area of the first surface of the anode.

The bank may have a concave side surface.

An angle made by a virtual line that is a shortest straight line from an end to the other end of the side surface of the bank and a top surface of the anode in contact with the bank may be less than 45 degrees.

The organic light-emitting unit may be disposed on the first surface of the anode, the side surface of the bank and at least a part of the top surface of the bank.

The bank may be formed by using a mask that has a region where transmittance gradually changes.

According to another aspect of the present disclosure, an organic light-emitting display (OLED) device includes: a substrate comprising a pixel area, an organic light-emitting element on the substrate, comprising an anode, cathode and an organic light-emitting unit, and a bank which surrounds the anode and covers ends of the anode. The pixel area is defined by a contact between a top surface of the anode and the bank. The anode is parallel with the cathode in the pixel area.

The bank may have an opening via which a part of the anode is exposed, wherein an area of a surface of the cathode in parallel with the exposed part of the anode is equal to or larger than an area of a bottom surface of the opening.

The emission area may be defined as an area where the anode is parallel with the cathode, the pixel area may be defined by a respective one among the anodes and the bank, and a size of the emission area may be equal to a size of the pixel area.

A distance between the anode and the cathode may be constant in the pixel area.

The opening may have a convex side surface.

An angle made by a virtual line that is a shortest straight line from an end to the other end of the side surface of the bank and the bottom surface of the opening may be larger than 135 degrees.

The bank may be formed by using a mask that has a region where transmittance gradually changes.

The organic light-emitting unit may be disposed on the top surface of the anode exposed via the opening of the bank, the side surface of the bank and at least a part of the top surface of the bank.

According to still another aspect of the present disclosure, an organic light-emitting display (OLED) device includes: an organic light-emitting element comprising a plurality of anodes spaced apart from one another and a cathode on the anodes in each pixel area, and a bank defining the pixel area and covering ends of each of the anodes. The bank has a concave side surface configured to minimize reduction in an emission area relative to the pixel area according to increase in thickness of the organic light-emitting element.

The emission area may be defined as an area where the anode is parallel with the cathode. The pixel area may be defined by a portion where one among the anodes contacts the bank. A size of the emission area may be equal to a size of the pixel area

Each of the anodes may comprise a first surface being opened by the bank. The cathode may have a second surface in parallel with the first surface. An area of the second surface may be equal to or larger than an area of the first surface.

The organic light-emitting element may comprise an organic light-emitting unit between the anodes and the cathode. The organic light-emitting unit may be disposed on the first surface of the anodes, a side surface of the bank and at least a part of a top surface of the bank.

A distance between one of the anodes and the cathode may be constant in the pixel area.

An angle made by a virtual line that is a shortest straight line from an end to the other end of the side surface of the bank and top surfaces of the anodes in contact with the bank may be less than 45 degrees.

The bank may be formed by using a mask that has a region where transmittance gradually changes.

It will be apparent to those skilled in the art that various modifications and variations can be made in the organic light-emitting display device of the present invention without departing from the spirit or scope of the invention. Thus, it is intended that the present invention cover the modifications and variations of this invention provided they come within the scope of the appended claims and their equivalents.

What is claimed is:

1. An organic light-emitting display (OLED) device, comprising:
an anode on a substrate;
a bank surrounding the anode, and exposing a first surface of the anode;
an organic light-emitting unit on the anode; and
a cathode on the organic light-emitting unit,the cathode having a second surface in parallel with the first surface of the anode,
wherein the bank has a structure that includes an area of the second surface of the cathode equal to or larger than an area of the first surface of the anode.

2. The OLED device of claim 1, wherein the bank has a concave side surface.

3. The OLED device of claim 2, wherein an angle between a virtual line that is a shortest straight line from an end to the other end of the side surface of the bank and a top surface of the anode in contact with the bank is less than 45 degrees.

4. The OLED device of claim 2, wherein the organic light-emitting unit is on the first surface of the anode, the side surface of the bank and at least one part of the top surface of the bank.

5. The OLED device of claim 2, wherein the bank is formed by using a mask that has a region where transmittance gradually changes.

6. An organic light-emitting display (OLED) device, comprising:
a substrate comprising a pixel area;
an organic light-emitting element on the substrate, the organic light-emitting element having an anode, cathode and an organic light-emitting unit; and
a bank surrounding the anode, and covering an end of the anode,
wherein the pixel area is defined by a contact between a top surface of the anode and the bank, and
the anode is parallel with the cathode in the pixel area.

7. The OLED device of claim 6, wherein the bank has an opening which a part of the anode is exposed, and wherein an area of a surface of the cathode in parallel with the exposed part of the anode is equal to or larger than an area of a bottom surface of the opening.

8. The OLED device of claim 7, wherein a distance between the anode and the cathode is constant in the pixel area.

9. The OLED device of claim 8, wherein the opening has a convex side surface.

10. The OLED device of claim 9, wherein an angle between a virtual line that is a shortest straight line from an end to the other end of the side surface of the bank and the bottom surface of the opening is larger than 135 degrees.

11. The OLED device of claim 9, wherein the bank is formed by using a mask that has a region where transmittance gradually changes.

12. The OLED device of claim 8, wherein the organic light-emitting unit is on at least one part among the top surface of the anode exposed via the opening of the bank, the side surface of the bank and the top surface of the bank.

13. An organic light-emitting display (OLED) device, comprising:
an organic light-emitting element comprising a plurality of anodes spaced apart from one another and a cathode on the anodes in each pixel area; and
a bank defining each pixel area and covering ends of each of the anodes,
wherein the bank has a concave side surface configured to minimize reduction in an emission area relative to the pixel area according to increase in thickness of the organic light-emitting element.

14. The OLED device of claim 13, wherein:
the emission area includes an area where the anode is parallel with the cathode,
the pixel area includes a portion where one of the anodes contacts the bank, and
a size of the emission area is equal to a size of the pixel area.

15. The OLED device of claim 14, wherein:
each of the anodes comprises a first surface being opened by the bank,
the cathode has a second surface in parallel with the first surface, and
an area of the second surface is equal to or larger than an area of the first surface.

16. The OLED device of claim 15, wherein the organic light-emitting element comprises an organic light-emitting unit between the anodes and the cathode,
wherein the organic light-emitting unit is on at least one part among the first surface of the anodes, a side surface of the bank and a top surface of the bank.

17. The OLED device of claim 15, wherein a distance between one of the anodes and the cathode is constant in the pixel area.

18. The OLED device of claim 14, wherein an angle between a virtual line that is a shortest straight line from an end to the other end of the side surface of the bank and top surfaces of the anodes in contact with the bank is less than 45 degrees.

19. The OLED device of claim 14, wherein the bank is formed by using a mask that has a region where transmittance gradually changes.
